(19) United States
(12) Patent Application Publication
(10) Pub. No.: US 2026/0150738 A1
(43) Pub. Date: May 28, 2026

(54) SEMICONDUCTOR PACKAGE

(71) Applicant: SAMSUNG ELECTRONICS CO., LTD., Suwon-si (KR)

(72) Inventors: Hyeonjae KIM, Suwon-si (KR); Yukyung PARK, Suwon-si (KR); Seungkwan RYU, Suwon-si (KR)

(73) Assignee: SAMSUNG ELECTRONICS CO., LTD., Suwon-si (KR)

(21) Appl. No.: 19/384,427

(22) Filed: Nov. 10, 2025

(30) Foreign Application Priority Data
Nov. 28, 2024 (KR) 10-2024-0174170

(51) Int. Cl. H10W 70/685; H10W 72/50; H10W 74/10; H10W 90/00

(52) U.S. Cl. CPC H10W 70/685; H10W 72/50; H10W 74/117; H10W 90/00; H10W 90/701

(57) ABSTRACT

A semiconductor package may include a first redistribution layer (RDL) including: a first insulating interlayer structure including a first insulating interlayer; a first redistribution wiring in the first insulating interlayer structure; a first conductive pad on the first insulating interlayer, a sidewall of the first conductive pad having an inclination with respect to an upper surface of the at least one first insulating interlayer; and a first protective layer on the at least one first insulating interlayer, and on the sidewall of the first conductive pad and an edge of an upper surface of the first conductive pad, the first protective layer including a photo imageable dielectric (PID). The semiconductor package may further include: a first semiconductor chip on the first RDL, the first semiconductor chip electrically connected to the first conductive pad; and a first molding layer on the first RDL and the first semiconductor chip.

### CROSS-REFERENCE TO RELATED APPLICATION

This application claims priority under 35 U.S.C. § 119 to Korean Patent Application No. 10-2024-0174170, filed on November 28, 2024, in the Korean Intellectual Property Office (KIPO), the disclosure of which is herein incorporated by reference in its entirety.

### BACKGROUND

### 1. Field

Some example embodiments of the present disclosure relate to a semiconductor package.

### 2. Description of Related Art

When a redistribution layer (RDL) is formed, conductive pads may be formed and a protective layer may be formed to cover the conductive pads. During the formation of the protective layer, micro bubbles may be generated, and the micro bubbles may expand or burst in subsequent high-temperature processes to damage surrounding structures.

### SUMMARY

According to some example embodiments of the present disclosure, a semiconductor package having enhanced electrical characteristics may be provided.

According to some example embodiments of the present disclosure, a semiconductor package may be provide and include a first redistribution layer (RDL) including: a first insulating interlayer structure including at least one first insulating interlayer; at least one first redistribution wiring in the first insulating interlayer structure; a first conductive pad on an uppermost one of the at least one first insulating interlayer, a sidewall of the first conductive pad having an inclination with respect to an upper surface of the uppermost one of the at least one first insulating interlayer; and a first protective layer on the uppermost one of the at least one first insulating interlayer, and on the sidewall of the first conductive pad and an edge of an upper surface of the first conductive pad, the first protective layer including a photo imageable dielectric (PID). The semiconductor package may further include: a first semiconductor chip on the first RDL, the first semiconductor chip electrically connected to the first conductive pad; and a first molding layer on the first RDL and the first semiconductor chip.

According to some example embodiments of the present disclosure, a semiconductor package may be provide and include a redistribution layer (RDL) including: an insulating interlayer including an inorganic insulating material; a redistribution wiring in the insulating interlayer; a first conductive pad on the insulating interlayer, a sidewall of the first conductive pad having an inclination with respect to an upper surface of the insulating interlayer; a second conductive pad spaced apart from the first conductive pad in a horizontal direction on the insulating interlayer, a sidewall of the second conductive pad being perpendicular with respect to the upper surface of the insulating interlayer; and a protective layer on the insulating interlayer, and on a sidewall of each of the first conductive pad and the second conductive pad and an edge of an upper surface of each of the first conductive pad and the second conductive pad, the protective layer including a photo imageable dielectric (PID). The semiconductor package may further include: a semiconductor chip on the RDL, the semiconductor chip electrically connected to the first conductive pad and the second conductive pad; and a molding layer on the RDL and the semiconductor chip.

According to some example embodiments of the present disclosure, a semiconductor package may be provide and include a first redistribution layer (RDL) including: at least one first insulating interlayer; at least one first redistribution wiring in the first insulating interlayer structure; a first conductive pad on an uppermost one of the at least one first insulating interlayer, a sidewall of the first conductive pad having an inclination with respect to an upper surface of the uppermost one of the at least one first insulating interlayer; and a first protective layer on the uppermost one of the at least one first insulating interlayer, and on the sidewall of the first conductive pad and an edge of an upper surface of the first conductive pad. The semiconductor package may further include: a first conductive connection member on a lower surface of the first RDL and contacting a portion of the at least one first redistribution wiring; a second conductive connection member on the first RDL and contacting the first conductive pad; a first semiconductor chip on an upper surface of the second conductive connection member; a first molding layer on the first RDL, the first semiconductor chip, and the second conductive connection member; a second RDL on the first molding layer, the second RDL including at least one second redistribution wiring and a second conductive pad; a third conductive connection member on the second RDL and contacting the second conductive pad; and a second semiconductor chip contacting an upper surface of the third conductive connection member.

In a semiconductor package according to an embodiment of the present disclosure, the conductive pads may not have a perpendicular sidewall but may have a slanted sidewall, and thus micro bubbles generated in the protective layer covering the conductive pads may not be trapped by the sidewalls of the conductive pads, but may be easily emitted outwardly. Thus, damage of neighboring structures by the micro bubbles may be prevented, so that the semiconductor package may have enhanced structural stability.

As the sidewalls of the conductive pads are slanted, a portion of the protective layer covering an upper portion of the sidewall and an upper surface of an edge of each of the conductive pads may have a relatively large thickness. Accordingly, each of the conductive pads may be well protected by the protective layer so that the semiconductor package may have enhanced electrical characteristics.

### BRIEF DESCRIPTION OF DRAWINGS

FIG. 1 is a cross-sectional view illustrating a semiconductor package in accordance with example embodiments of the present disclosure.

FIGS. 2 to 9 are cross-sectional views illustrating a method of manufacturing a semiconductor package in accordance with example embodiments of the present disclosure.

FIGS. 10 and 11 are cross-sectional views illustrating a semiconductor package in accordance with example embodiments of the present disclosure.

### DETAILED DESCRIPTION

Hereinafter, non-limiting example embodiments of the present disclosure will be explained in detail with reference to the accompanying drawings. A direction parallel to an upper surface of a substrate, chip, or redistribution layer may be referred to as a horizontal direction, and a direction perpendicular to the upper surface of the substrate, chip, or redistribution layer may be referred to as a vertical direction.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

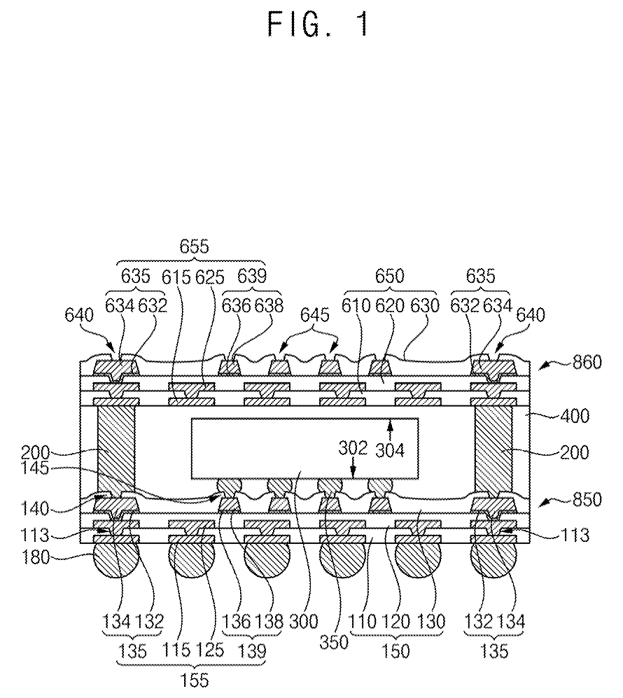

FIG. 1 is a cross-sectional view illustrating a semiconductor package in accordance with example embodiments of the present disclosure.

Referring to FIG. 1, the semiconductor package may include a first redistribution layer (RDL) 850, a first semiconductor chip 300, a conductive post 200, a first molding layer 400, a second RDL 860, a first conductive connection member 180, and a second conductive connection member 350.

The first RDL 850 may include a first insulating interlayer structure 150, and a first redistribution wiring structure 155 in the first insulating interlayer structure 150. The first redistribution wiring structure 155 may include, for example, redistribution wirings, conductive pads, vias, contact plugs, etc.

FIG. 1 shows that the first insulating interlayer structure 150 of the first RDL 850 may include a first insulating interlayer 110, a second insulating interlayer 120, and a third insulating interlayer 130 sequentially stacked in the vertical direction, and the first redistribution wiring structure 155 may include a redistribution wiring 115, a second redistribution wiring 125, a first conductive pad 135, and a second conductive pad 139.

However, embodiments of the present disclosure are not limited thereto, and the first insulating interlayer structure 150 of the first RDL 850 may include more or less than three insulating interlayers, and the first redistribution wiring structure 155 may include more redistribution wirings or conductive pads than shown in FIG. 1, or may include vias and contact plugs. The redistribution wirings, the conductive pads, the vias and the contact plugs included in the first redistribution wiring structure 155 may have various layouts in the insulating interlayers.

In example embodiments, a sidewall of each of the first redistribution wiring 115 and the second redistribution wiring 125 may be perpendicular to an upper surface of the first insulating interlayer 110 or an upper surface of the second insulating interlayer 120.

The first insulating interlayer 110 may cover a sidewall and an upper surface of the first redistribution wiring 115. A portion of the second redistribution wiring 125 may extend through the first insulating interlayer 110, and may contact an upper surface of a portion of the first redistribution wiring 115. The second insulating interlayer 120 may cover a sidewall and an upper surface of the second redistribution wiring 125.

The first conductive pad 135 may include a lower portion extending through the second insulating interlayer 120 and contacting the upper surface of the second redistribution wiring 125, and an upper portion disposed on the lower portion and contacting the upper surface of the second insulating interlayer 120. Additionally, the second conductive pad 139 may contact the upper surface of the second insulating interlayer 120.

The first conductive pad 135 may include a first seed pattern 132 and a first conductive pattern 134 stacked in the vertical direction, and the second conductive pad 139 may include a second seed pattern 136 and a second conductive pattern 138 stacked in the vertical direction.

In example embodiments, a sidewall of the upper portion of the first conductive pad 135 and a sidewall of the second conductive pad 139 may have an inclination of about 70° to about 80° with respect to the upper surface of the first insulating interlayer 110 or the upper surface of the second insulating interlayer 120. Thus, a cross-section in the vertical direction of the upper portion of the first conductive pad 135 and the second conductive pad 139 may have a shape of a trapezoid. In an example embodiment, the upper portion of the first conductive pad 135 and the second conductive pad 139 may have a thickness of about 1 um to about 5 um in the vertical direction.

In example embodiments, a plurality of first conductive pads 135 may be spaced apart from each other in the horizontal direction, and a plurality of second conductive pads 139 may be spaced apart from each other in the horizontal direction. In an example embodiment, the sidewalls of the upper portions of all of the first conductive pads 135 and the sidewalls of all of the second conductive pads 139 may have an inclination of about 70° to about 80° with respect to the upper surface of the first insulating interlayer 110 or the upper surface of the second insulating interlayer 120.

Alternatively, the sidewalls of the upper portions of some ones of the first conductive pads 135 may have an inclination of about 70° to about 80° with respect to the upper surface of the first insulating interlayer 110 or the upper surface of the second insulating interlayer 120, while the sidewalls of the upper portions of other ones of the first conductive pads 135 may be perpendicular with respect to the upper surface of the first insulating interlayer 110 or the upper surface of the second insulating interlayer 120. Likewise, the sidewalls of the upper portions of some ones of the second conductive pads 139 may have an inclination of about 70° to about 80° with respect to the upper surface of the first insulating interlayer 110 or the upper surface of the second insulating interlayer 120, while the sidewalls of the upper portions of other ones of the second conductive pads 139 may be perpendicular with respect to the upper surface of the first insulating interlayer 110 or the upper surface of the second insulating interlayer 120.

In an example embodiment, the first conductive pads 135 may be arranged in a ring shape at an edge portion of the second insulating interlayer 120 in a plan view, and the second conductive pads 139 may be arranged on a central portion of the second insulating interlayer 120 in a plan view.

The third insulating interlayer 130 may cover and protective an upper surface and the sidewall of the upper portion of the first conductive pad 135 and an upper surface and the sidewall of the second conductive pad 139, and thus may also be referred to as a first protective layer. However, the third insulating interlayer 130 may include a fifth opening 140 partially exposing the upper surface of the upper portion of the first conductive pad 135 and a sixth opening 145 partially exposing the upper surface of the second conductive pad 139.

In example embodiments, a diameter of the fifth opening 140 may be smaller than a diameter of the upper portion of the first conductive pad 135, and a diameter of the sixth opening 145 may be smaller than a diameter of the second conductive pad 139. That is, the third insulating interlayer 130 may cover an upper surface and a sidewall of an edge of the upper portion of the first conductive pad 135, and an upper surface and a sidewall of an edge of the second conductive pad 139.

Each of the first insulating interlayer 110 and the second insulating interlayer 120 may include an inorganic insulating material such as, for example, silicon oxide, silicon nitride, etc.

In example embodiments, the third insulating interlayer 130 may include an organic insulating material such as, for example, photo imageable dielectric (PID). The organic insulating material may include, for example, polybenzoxazole (PBO), polyimide, etc. The redistribution wirings, the conductive pads, the vias, the contact plugs, etc., included in the first redistribution wiring structure 155 may include a metal such as, for example, copper, aluminum, nickel, gold, etc., a metal nitride, a metal silicide, etc. The seed pattern and the conductive pattern included in each of the conductive pads may include substantially the same material as each other or different materials from each other.

The first conductive connection member 180 may be disposed on a lower surface of the first RDL 850, and may contact a portion of the first redistribution wiring structure 155, particularly, a lower surface of the first redistribution wiring 115. In example embodiments, a plurality of first conductive connection members 180 may be spaced apart from each other in the horizontal direction, and may be disposed on a package substrate such as printed circuit board (PCB), a mother board, etc., and electrically connected thereto.

The first conductive connection member 180 may include, for example, a conductive ball or a conductive bump, and may include solder, which may be an alloy of tin, silver, copper, lead, etc., or a metal such as copper, aluminum, nickel, etc.

The first semiconductor chip 300 may be mounted on the first RDL 850 via the second conductive connection member 350, which may extend through the third insulating interlayer 130 and contact a portion of the first redistribution wiring structure 155, that is, the upper surface of the second conductive pad 139, and thus may be electrically connected to the first redistribution wiring structure 155. The first semiconductor chip 300 may include a first surface 302 and a second surface 304 opposite to each other in the vertical direction. The first surface 302 of the first semiconductor chip 300 may face downwardly in the vertical direction, and may contact an upper surface of the second conductive connection member 350.

The first semiconductor chip 300 may include a volatile memory device such as a dynamic random-access memory (DRAM) device, a static random-access memory (SRAM) device, etc., or a non-volatile memory device such as a flash memory device, an electrically erasable programmable read-only memory (EEPROM) device, etc. Alternatively, the first semiconductor chip 300 may include a logic device such as a controller.

The first molding layer 400 may be disposed on the first RDL 850, and may cover the first semiconductor chip 300 and the second conductive connection member 350. The first molding layer 400 may include, for example, epoxy molding compound (EMC).

The conductive post 200 may extend through the first molding layer 400 in the vertical direction, and may contact the first conductive pad 135 to be electrically connected thereto. In example embodiments, a plurality of conductive posts 200 may be spaced apart from each other in the horizontal direction, and may be arranged to surround the first semiconductor chip 300 in a plan view.

In an example embodiment, an upper surface of the conductive post 200 may be higher than an upper surface of the first semiconductor chip 300. Alternatively, the upper surface of the conductive post 200 may be substantially coplanar with the upper surface of the first semiconductor chip 300.

The conductive post 200 may include a metal such as, for example, copper, aluminum, etc.

The second RDL 860 may include a second insulating interlayer 650 and a second redistribution wiring structure 655 in the second insulating interlayer 650. The second redistribution wiring structure 655 may include wirings, conductive pads, vias, contact plugs, etc.

FIG. 1 shows that the second insulating interlayer 650 of the second RDL 860 may include a fourth insulating interlayer 610, a fifth insulating interlayer 620, and a sixth insulating interlayer 630 sequentially stacked in the vertical direction, and the second redistribution wiring structure 655 may include a third redistribution wiring 615, a fourth redistribution wiring 625, a third conductive pad 635, and a fourth conductive pad 639.

However, embodiments of the present disclosure are not limited thereto, and the second insulating interlayer 650 of the second RDL 860 may include more or less than three insulating interlayers, and the second redistribution wiring structure 655 may include more redistribution wirings or conductive pads than shown in FIG. 1, or may include vias and contact plugs.

The fourth insulating interlayer 610 may cover a sidewall and an upper surface of the third redistribution wiring 615. A portion of the fourth redistribution wiring 625 may extend through the fourth insulating interlayer 610, and may contact an upper surface of a portion of the third redistribution wiring 615. The fifth insulating interlayer 620 may cover a sidewall and an upper surface of the fourth redistribution wiring 625.

The third conductive pad 635 may include a lower portion extending through the fifth insulating interlayer 620 and contacting the upper surface of the fourth redistribution wiring 625, and an upper portion disposed on the lower portion and contacting the upper surface of the fifth insulating interlayer 620. Additionally, the fourth conductive pad 639 may contact the upper surface of the fifth insulating interlayer 620.

The third conductive pad 635 may include a third seed pattern 632 and a third conductive pattern 634 stacked in the vertical direction, and the fourth conductive pad 639 may include a fourth seed pattern 636 and a fourth conductive pattern 638 stacked in the vertical direction.

In example embodiments, a sidewall of the upper portion of the third conductive pad 635 and a sidewall of the fourth conductive pad 639 may have an inclination of about 70° to about 80° with respect to the upper surface of the fourth insulating interlayer 610 or the upper surface of the fifth insulating interlayer 620. Thus, a cross-section in the vertical direction of the upper portion of the third conductive pad 635 and the fourth conductive pad 639 may have a shape of a trapezoid. In an example embodiment, the upper portion of the third conductive pad 635 and the fourth conductive pad 639 may have a thickness of about 1 um to about 5 um in the vertical direction.

In example embodiments, a plurality of third conductive pads 635 may be spaced apart from each other in the horizontal direction, and a plurality of fourth conductive pads 639 may be spaced apart from each other in the horizontal direction. In an example embodiment, the sidewalls of the upper portions of all of the third conductive pads 635 and the sidewalls of all of the fourth conductive pads 639 may have an inclination of about 70° to about 80° with respect to the upper surface of the fourth insulating interlayer 610 or the upper surface of the fifth insulating interlayer 620.

Alternatively, the sidewalls of the upper portions of some ones of the third conductive pads 635 may have an inclination of about 70° to about 80° with respect to the upper surface of the fourth insulating interlayer 610 or the upper surface of the fifth insulating interlayer 620, while the sidewalls of the upper portions of other ones of the third conductive pads 635 may be perpendicular with respect to the upper surface of the fourth insulating interlayer 610 or the upper surface of the fifth insulating interlayer 620. Likewise, the sidewalls of the upper portions of some ones of the fourth conductive pads 639 may have an inclination of about 70° to about 80° with respect to the upper surface of the fourth insulating interlayer 610 or the upper surface of the fifth insulating interlayer 620, while the sidewalls of the upper portions of other ones of the fourth conductive pads 639 may be perpendicular with respect to the upper surface of the fourth insulating interlayer 610 or the upper surface of the fifth insulating interlayer 620.

In an example embodiment, the third conductive pads 635 may be arranged in a ring shape at an edge portion of the fifth insulating interlayer 620 in a plan view, and the fourth conductive pads 639 may be arranged on a central portion of the fifth insulating interlayer 620 in a plan view.

The sixth insulating interlayer 630 may cover and protective an upper surface and the sidewall of the upper portion of the third conductive pad 635 and an upper surface and the sidewall of the fourth conductive pad 639, and thus may also be referred to as a second protective layer. However, the sixth insulating interlayer 630 may include an eighth opening 640 partially exposing the upper surface of the upper portion of the third conductive pad 635 and a ninth opening 645 partially exposing the upper surface of the fourth conductive pad 639.

In example embodiments, a diameter of the eighth opening 640 may be smaller than a diameter of the upper portion of the third conductive pad 635, and a diameter of the ninth opening 645 may be smaller than a diameter of the fourth conductive pad 639. That is, the sixth insulating interlayer 630 may cover an upper surface and a sidewall of an edge of the upper portion of the third conductive pad 635, and an upper surface and a sidewall of an edge of the fourth conductive pad 639.

Each of the fourth insulating interlayer 610 and the fifth insulating interlayer 620 may include an inorganic insulating material such as, for example, silicon oxide, silicon nitride, etc. The sixth insulating interlayer 630 may include an organic insulating material such as, for example, PID. The redistribution wirings, the conductive pads, the vias, the contact plugs, etc., included in the second redistribution wiring structure 655 may include a metal such as, for example, copper, aluminum, nickel, gold, etc., a metal nitride, a metal silicide, etc.

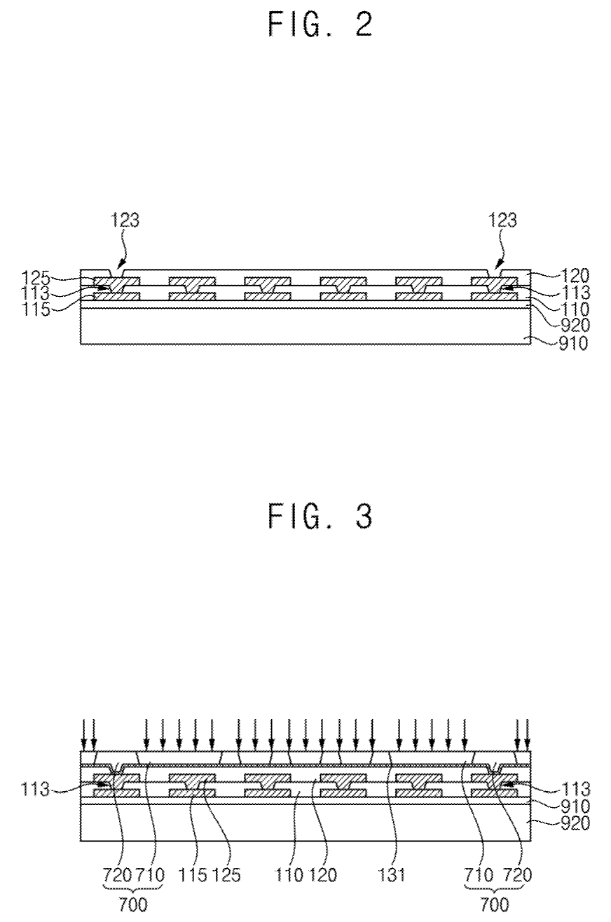

In the semiconductor package, the sidewall of each of the first conductive pad 135 and the second conductive pad 139 may not be perpendicular but slanted with respect to the upper surface of the first insulating interlayer 110 or the upper surface of the second insulating interlayer 120. Thus, as described below with reference to FIGS. 2 to 9, when the third insulating interlayer 130 is formed on the second insulating interlayer 120 to cover the first conductive pad 135 and the second conductive pad 139, micro bubbles generated in the third insulating interlayer 130 may not be trapped in the third insulating interlayer 130, but may be easily emitted outwardly. Thus, the micro bubbles may not remain in the third insulating interlayer 130. Accordingly, damages of neighboring structures by the micro bubbles may be prevented, so that the semiconductor package including the third insulating interlayer 130 may have enhanced structural stability.

As the sidewall of each of the first conductive pad 135 and the second conductive pad 139 is slanted with respect to the upper surface of the first insulating interlayer 110 or the upper surface of the second insulating interlayer 120, when compared to a case in which a sidewall of each of the first conductive pad 135 and the second conductive pad 139 is perpendicular to the upper surface of the first insulating interlayer 110 or the upper surface of the second insulating interlayer 120, a portion of the third insulating interlayer 130 covering an upper portion of the sidewall and an upper surface of an edge of each of the first conductive pad 135 and the second conductive pad 139 may have a relatively large thickness. Accordingly, each of the first conductive pad 135 and the second conductive pad 139 may be well protected by the third insulating interlayer 130 so that the semiconductor package may have enhanced electrical characteristics.

FIGS. 2 to 9 are cross-sectional views illustrating a method of manufacturing a semiconductor package in accordance with example embodiments.

Referring to FIG. 2, a first temporary adhesion layer 920 may be attached to a first carrier substrate 910, and the first insulating interlayer 110, the second insulating interlayer 120, the first redistribution wiring 115, and the second redistribution wiring 125 may be formed on the first temporary adhesion layer 920.

The first carrier substrate 910 may include, for example, a non-metallic or metallic plate, a silicon substrate, a glass substrate, etc. The first temporary adhesion layer 920 may include a material configured to lose adhesion by irradiation of light or heating thereto, or glue, release tape, etc.

The first redistribution wiring 115 may be formed on the first temporary adhesion layer 920. The first insulating interlayer 110 may be formed on the first temporary adhesion layer 920 to cover the first redistribution wiring 115, and may have a first opening 113 exposing an upper surface of a portion of the first redistribution wiring 115. The second redistribution wiring 125 may be formed on the first insulating interlayer 110, and may contact a portion of the first redistribution wiring 115. The second insulating interlayer 120 may be formed on the first insulating interlayer 110 to cover the second redistribution wiring 125, and may have a second opening 123 exposing an upper surface of a portion of the second redistribution wiring 125.

In example embodiments, each of the first redistribution wiring 115 and the second redistribution wiring 125 may be formed by, for example, an electroplating process or an electroless plating process, and each of the first insulating interlayer 110 and the second insulating interlayer 120 may be formed by a deposition process such as, for example, a chemical vapor deposition (CVD) process, an atomic layer deposition (ALD) process, etc.

Referring to FIG. 3, a first seed layer 131 may be formed on an upper surface of the second insulating interlayer 120, a sidewall of the second opening 123, and the upper surface of the portion of the second redistribution wiring 125 exposed by the second opening 123, a first photoresist layer 700 may be formed on the first seed layer 131, and an exposure process may be performed on the first photoresist layer 700.

By the exposure process, the first photoresist layer 700 may be divided into an exposed portion 710 and an unexposed portion 720.

In example embodiments, the first photoresist layer 700 may be a negative photoresist layer, and thus a bonding of a polymer contained in the first photoresist layer 700 may be strengthen by an irradiated light. Additionally, a chemical reaction may expand in the horizontal direction due to a photo active compound (PAC) in the first photoresist layer 700. Thus, an upper portion of the exposed portion 710 directly exposed to the irradiated light may be formed to have an area greater than an area of a lower portion.

Accordingly, a sidewall of the exposed portion 710 may not be perpendicular, but may have an inclination of about 70° to about 80° with respect to an upper surface of the first carrier substrate 910, an upper surface of the first insulating interlayer 110 or the upper surface of the second insulating interlayer 120.

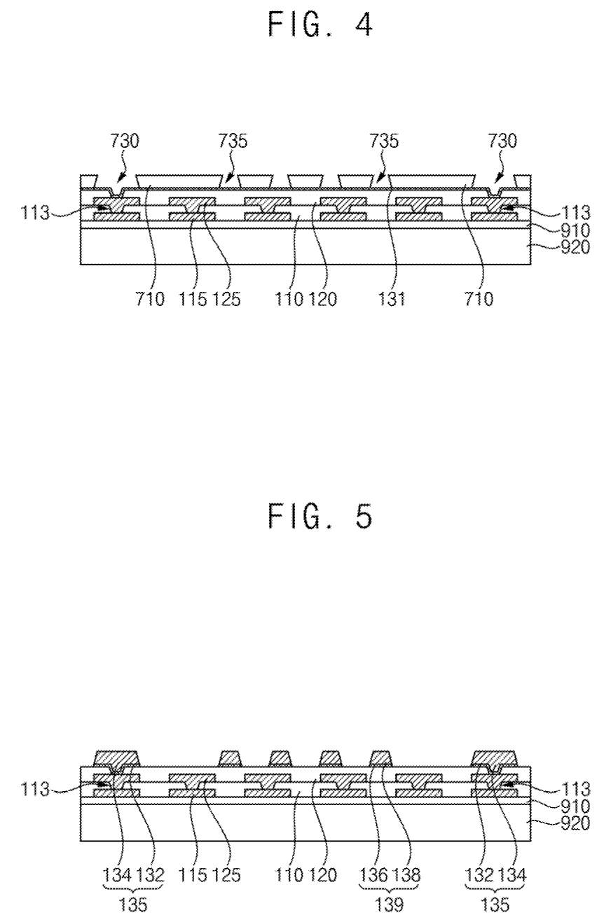

Referring to FIG. 4, a development process may be performed on the first photoresist layer 700, and thus the exposed portion 710 in which the bonding of the polymer has been strengthen by the irradiated light may remain, while the unexposed portion 720 in which the bonding of the polymer is relatively weak may be removed.

As the unexposed portion 720 is removed, a third opening 730 exposing a portion of the first seed layer 131 on the upper surface of the portion of the second redistribution wiring 125 exposed by the second opening 123 and the sidewall of the second opening 123, and a fourth opening 735 exposing a portion of the first seed layer 131 on the upper surface of the second insulating interlayer 120 may be formed. An upper sidewall of the third opening 730 and a sidewall of the fourth opening 735 may have an inclination of about 70° to about 80° with respect to the upper surface of the first carrier substrate 910, the upper surface of the first insulating interlayer 110 or the upper surface of the second insulating interlayer 120.

Referring to FIG. 5, for example, an electroplating process or an electroless plating process may be performed to form a first conductive pattern 134 and a second conductive pattern 138 on portions of the first seed layer 131 exposed by the third opening 730 and the fourth opening 735, respectively.

The exposed portion 710 of the first photoresist layer 700 may be removed by, for example, an ashing process and/or a stripping process to expose a portion of the first seed layer 131, and the exposed portion of the first seed layer 131 may be removed by, for example, a wet etching process to form a first seed pattern 132 and a second seed pattern 136 on the first conductive pattern 134 and the second conductive pattern 138, respectively.

Thus, a first conductive pad 135 including a first seed pattern 132 and a first conductive pattern 134 sequentially stacked, and a second conductive pad 139 including a second seed pattern 136 and a second conductive pattern 138 sequentially stacked may be formed. The first conductive pad 135 may include a lower portion having a relatively small width and an upper portion stacked on the lower portion and having a relatively large width.

In example embodiments, a sidewall of the upper portion of the first conductive pad 135 and a sidewall of the second conductive pad 139 may have an inclination of about 70° to about 80° with respect to the upper surface of the first carrier substrate 910, the upper surface of the first insulating interlayer 110 or the upper surface of the second insulating interlayer 120.

In example embodiments, a plurality of first conductive pads 135 may be spaced apart from each other in the horizontal direction, and a plurality of second conductive pads 139 may be spaced apart from each other in the horizontal direction. In an example embodiment, the first conductive pads 135 may be arranged in a ring shape at an edge of the second insulating interlayer 120, and the second conductive pads 139 may be arranged at a central portion of the second insulating interlayer 120.

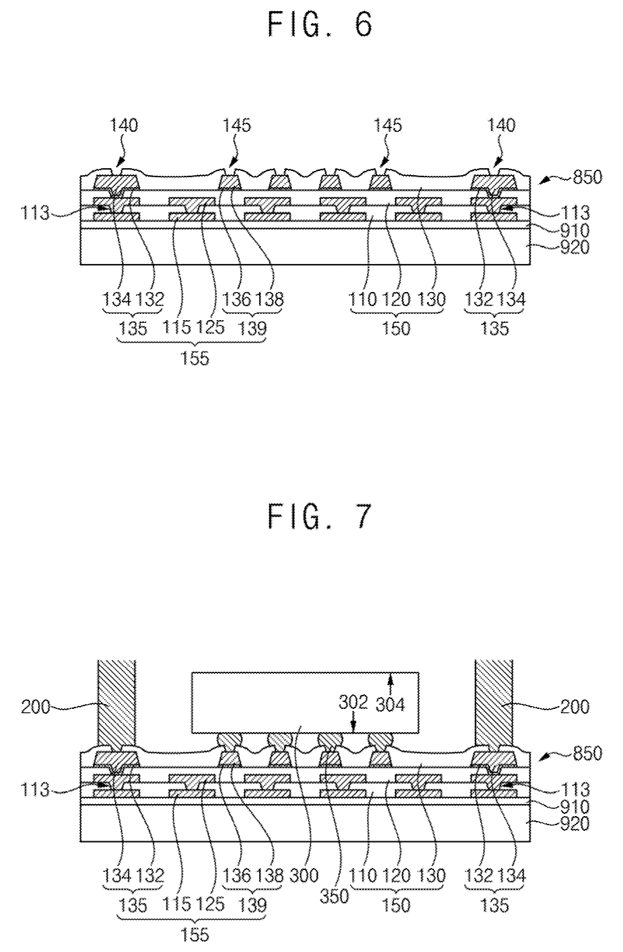

Referring to FIG. 6, a third insulating interlayer 130 may be formed on the second insulating interlayer 120 to cover the first conductive pad 135 and the second conductive pad 139, and the third insulating interlayer 130 may be partially removed to form a fifth opening 140 and a sixth opening 145 exposing upper surfaces of portions of the first conductive pad 135 and the second conductive pad 139, respectively.

In example embodiments, the third insulating interlayer 130 may be formed by a spin coating process, and after the spin coating process, a curing process may be further performed on the third insulating interlayer 130.

The third insulating interlayer 130 may be formed to include, for example, PID.

When the third insulating interlayer 130 is formed by the spin coating process, micro bubbles may be generated in the third insulating interlayer 130, but may be easily emitted outwardly.

If the sidewall of each of the first conductive pad 135 and the second conductive pad 139 is perpendicular to the upper surface of the first carrier substrate 910, the upper surface of the first insulating interlayer 110 or the upper surface of the second insulating interlayer 120, the micro bubbles in the third insulating interlayer 130 may not be easily emitted outwardly so as to be trapped in the third insulating interlayer 130. The micro bubbles trapped in the third insulating interlayer 130 may be outburst toward neighboring structures during a high temperature process such as a curing process.

However, in example embodiments, the sidewall of each of the first conductive pad 135 and the second conductive pad 139 may not be perpendicular, but slanted to the upper surface of the first carrier substrate 910, the upper surface of the first insulating interlayer 110 or the upper surface of the second insulating interlayer 120, and thus the micro bubbles in the third insulating interlayer 130 may be easily emitted outwardly so that the micro bubbles may be barely remain in the third insulating interlayer 130. As a result, during the high temperature process such as a curing process, damages of the neighboring structures due to the micro bubbles may be prevented, so that a structural stability of a structure including the third insulating interlayer 130 may be enhanced.

The first insulating interlayer 110, the second insulating layer 120, and the third insulating layer 130 sequentially stacked in the vertical direction may collectively form a first insulating interlayer structure 150, and the first redistribution wiring 115, the second redistribution wiring 125, the first conductive pad 135, and the second conductive pad 139 in the first insulating interlayer 110, the second insulating layer 120, and the third insulating layer 130 may collectively form a first redistribution wiring structure 155. The first insulating interlayer structure 150 and the first redistribution wiring structure 155 may collectively form a first redistribution layer (RDL) 850.

Referring to FIG. 7, a conductive post 200 may be formed to contact the first conductive pad 135, and a first semiconductor chip 300 may be mounted to be electrically connected to the second conductive pad 139.

In an example embodiment, the conductive post 200 may be formed by forming a second photoresist layer on the first RDL 850, forming a seventh opening to expose an upper surface of the first conductive pad 135, and performing, for example, an electroplating process or an electroless plating process in the seventh opening.

The second photoresist layer may be removed by, for example, an ashing process and/or a stripping process.

The first semiconductor chip 300 may be mounted on the second conductive pad 139 via a second conductive connection member 350 to be electrically connected to the second conductive pad 139. The second conductive connection member 350 may include, for example, a conductive ball or a conductive bump.

The first semiconductor chip 300 may include a first surface 302 and a second surface 304 opposite to each other in the vertical direction, and the first surface 302 of the first semiconductor chip 300 may face downwardly in the vertical direction.

In example embodiments, a plurality of conductive posts 200 may be spaced apart from each other in the horizontal direction, and may be arranged to surround the first semiconductor chip 300 in a plan view.

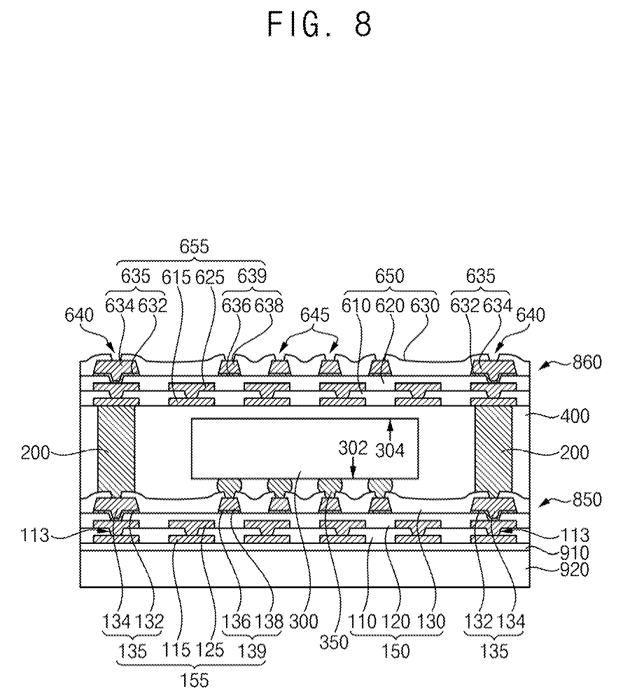

Referring to FIG. 8, a first molding layer 400 may be formed on the first RDL 850.

The first molding layer 400 may be formed to cover the first semiconductor chip 300, the second conductive connection member 350 and the conductive post 200.

For example, a grinding process may be performed on an upper portion of the first molding layer 400 to decrease a thickness of the first molding layer 400, and during the grinding process, an upper surface of the conductive post 200 may be exposed.

Processes substantially the same as or similar to those illustrated with respect to FIGS. 3 to 6 may be performed to form a second RDL 860 on the first molding layer 400 and the conductive post 200.

In example embodiments, the second RDL 860 may include a second insulating interlayer structure 650 having a fourth insulating interlayer 610, a fifth insulating interlayer 620, and a sixth insulating interlayer 630 sequentially stacked in the vertical direction, and a second redistribution wiring structure 655 having a third redistribution wiring 615, a fourth redistribution wiring 625, a third conductive pad 635, and a fourth conductive pad 639 in the fourth insulating interlayer 610, the fifth insulating interlayer 620, and the sixth insulating interlayer 630.

The sixth insulating interlayer 630 may include an eighth opening 640 and a ninth opening 645 exposing upper surfaces of portions of the third conductive pad 635 and the fourth conductive pad 639, respectively.

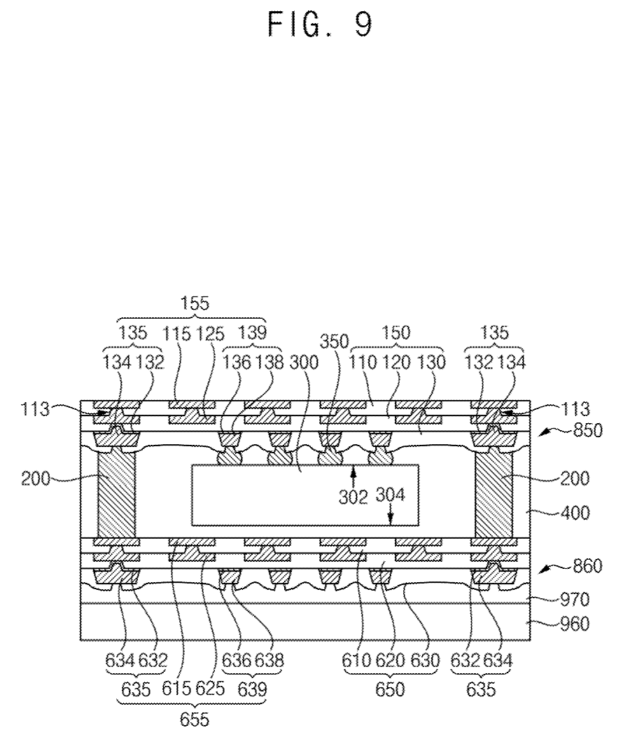

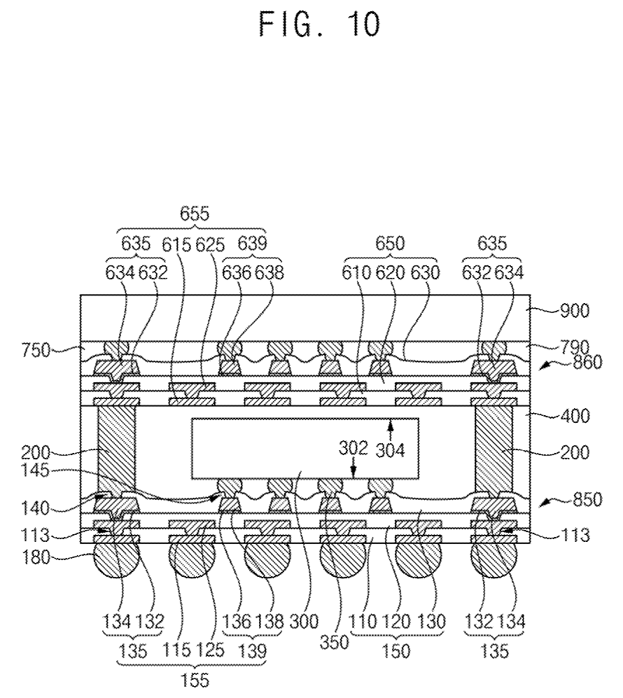

Referring to FIG. 9, a second temporary adhesion layer 970 and a second carrier substrate 960 may be attached to an upper surface of the second RDL 860, the second carrier substrate 960 may be flipped, and the first temporary adhesion layer 920 and the first carrier substrate 910 may be separated from the first RDL 850.

The second carrier substrate 960 may include, for example, a non-metallic or metallic plate, a silicon substrate, a glass substrate, etc. The second temporary adhesion layer 970 may include a material losing adhesion by irradiating light or heating thereto, or glue, release tape, etc.

Referring back to FIG. 1, a first conductive connection member 180 may be formed to contact a portion of the first redistribution wiring 115 included in the first RDL 850, the second carrier substrate 960 may be flipped, and the second carrier substrate 960 and the second temporary adhesion layer 970 may be removed to manufacture the semiconductor package.

As illustrated above, the first conductive pad 135 and the second conductive pad 139 may be formed by performing the exposure process and the development process on the first photoresist layer 700, which is a negative photoresist layer, on the second insulating interlayer 120 to form the third opening 730 and the fourth opening 735 having the sidewalls slanted with respect to the upper surface of the first carrier substrate 910, the upper surface of the first insulating interlayer or the upper surface of the second insulating interlayer 120, and performing the electroplating process or the electroless plating process.

Thus, the micro bubbles generated in the third insulating interlayer 130 covering the first conductive pad 135 and the second conductive pad 139 on the second insulating interlayer 120 may be easily emitted outwardly. Accordingly, during the high temperature process such as a curing process, damage of the neighboring structures due to the micro bubbles may be prevented so that the structural stability of the semiconductor package may be enhanced.

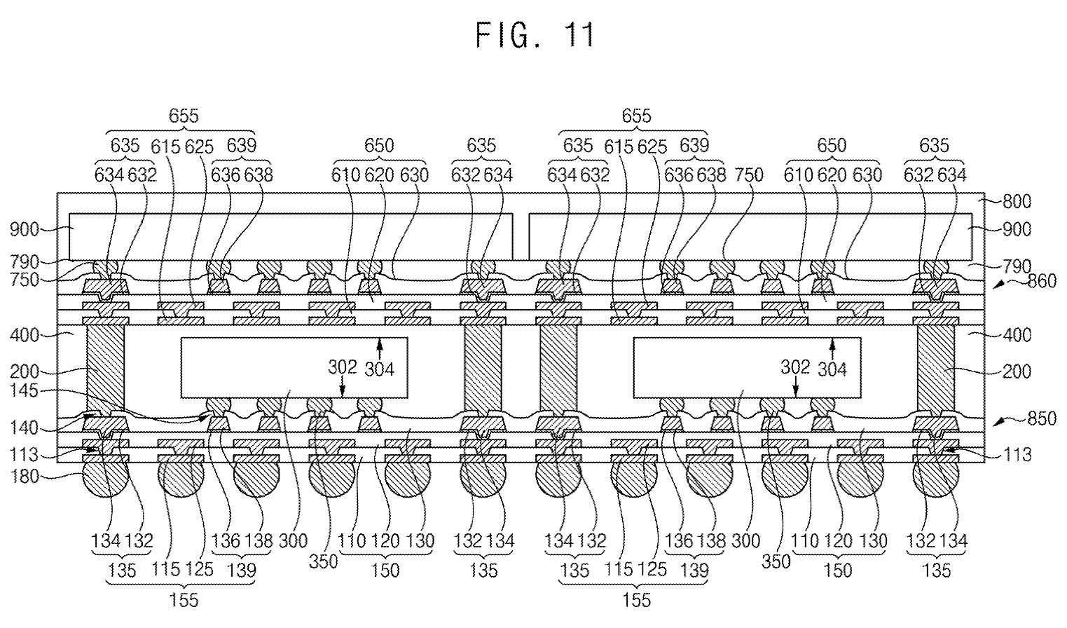

FIGS. 10 and 11 are cross-sectional views illustrating a semiconductor package in accordance with example embodiments.

This semiconductor package may be manufactured by stacking other semiconductor chips on the semiconductor package of FIG. 1, and repeated explanations may be omitted herein.

Referring to FIG. 10, a second semiconductor chip 900 may be mounted on the second RDL 860 via a third conductive connection member 750, and a second molding layer 790 may be interposed between the second RDL 860 and the second semiconductor chip 900 to cover the third conductive connection member 750.

In example embodiments, the second semiconductor chip 900 may be a memory chip including a memory device, and in this case, the first semiconductor chip 300 may be a logic chip including a logic device.

The third conductive connection member 750 may include a conductive ball or a conductive bump including solder or a metal, for example, copper, aluminum, nickel, etc.

The second molding layer 790 may include, for example, EMC. Alternatively, an underfill member including, for example, non-conductive paste (NCP), non-conductive film (NCF), etc., or an adhesion layer may be interposed between the second RDL 650 and the second semiconductor chip 900, instead of the second molding layer 790.

Referring to FIG. 11, two first semiconductor chips 300 may be spaced apart from each other in the horizontal direction on the first RDL 850, and two second semiconductor chips 900 may be spaced apart from each other in the horizontal direction on the second RDL 860.

In an example embodiment, each of the first semiconductor chip 300 and the second semiconductor chip 900 may be a memory chip including a memory device. Alternatively, each of the first semiconductor chips 300 may be a logic chip including a logic device, while each of the second semiconductor chips 900 may be a memory chip including a memory device.

FIG. 11 shows two first semiconductor chips 300 spaced apart from each other in the horizontal direction and two second semiconductor chips 900 spaced apart from each other in the horizontal direction. However, embodiments of the present disclosure are not limited thereto. For example, one or three or more first semiconductor chips 300 and one or three or more second semiconductor chips 900 may be mounted on the first RDL 850 and the second RDL 860, respectively.

A third molding layer 800 may be disposed on the second RDL 860, and may cover the second semiconductor chips 900 and the third conductive connection member 750. The third molding layer 800 may include, for example, EMC.

The foregoing is illustrative of example embodiments and is not to be construed as limiting the present disclosure. Although a few example embodiments have been described, those skilled in the art will readily appreciate that many modifications are possible in example embodiments without departing from the spirit and scope of the present disclosure. Accordingly, all such modifications are included within the scope of the present disclosure.

1. A semiconductor package comprising:
a first redistribution layer (RDL) comprising:
a first insulating interlayer structure comprising at least one first insulating interlayer;
at least one first redistribution wiring in the first insulating interlayer structure;
a first conductive pad on an uppermost one of the at least one first insulating interlayer, a sidewall of the first conductive pad having an inclination with respect to an upper surface of the uppermost one of the at least one first insulating interlayer; and
a first protective layer on the uppermost one of the at least one first insulating interlayer, and on the sidewall of the first conductive pad and an edge of an upper surface of the first conductive pad, the first protective layer comprising a photo imageable dielectric (PID);
a first semiconductor chip on the first RDL, the first semiconductor chip electrically connected to the first conductive pad; and
a first molding layer on the first RDL and the first semiconductor chip.

2. The semiconductor package according to claim 1, wherein the inclination of the sidewall of the first conductive pad is 70° to 80° with respect to the upper surface of the uppermost one of the at least one first insulating interlayer.

3. The semiconductor package according to claim 1, wherein the uppermost one of the at least one first insulating interlayer comprises an opening exposing an upper surface of a central portion of the first conductive pad, and
wherein the semiconductor package further comprises a first conductive connection member contacting the upper surface of the central portion of the first conductive pad and a lower surface of the first semiconductor chip.

4. The semiconductor package according to claim 1, wherein the first RDL further comprises:
a second conductive pad spaced apart from the first conductive pad in a horizontal direction, the second conductive pad comprising:
a lower portion extending through the uppermost one of the at least one first insulating interlayer and contacting a portion of the at least one first redistribution wiring; and
an upper portion on the lower portion, the upper portion comprising a sidewall slanted with respect to the upper surface of the uppermost one of the at least one first insulating interlayer.

5. The semiconductor package according to claim 4, wherein the first protective layer is on a sidewall of the second conductive pad and an edge of an upper surface of the second conductive pad.

6. The semiconductor package according to claim 5, further comprising a conductive post contacting the upper surface of the second conductive pad and extending in a vertical direction,
wherein the first molding layer is on a sidewall of the conductive post.

7. The semiconductor package according to claim 6, further comprising:
a second RDL on the first molding layer and the conductive post, the second RDL comprising:
a second insulating interlayer structure comprising at least one second insulating interlayer;
at least one second redistribution wiring in the second insulating interlayer structure , the at least one second redistribution wiring electrically connected to the conductive post;
a third conductive pad on an uppermost one of the at least one second insulating interlayer, a sidewall of the third conductive pad having an inclination with respect to an upper surface of the uppermost one of the at least one second insulating interlayer; and
a second protective layer on the uppermost one of the at least one second insulating interlayer, and on the sidewall of the third conductive pad and an edge of an upper surface of the third conductive pad, the second protective layer comprising a PID.

8. The semiconductor package according to claim 7, further comprising:
a second semiconductor chip on the second RDL, the second semiconductor chip electrically connected to the third conductive pad; and
a second molding layer on the second RDL and the second semiconductor chip.

9. The semiconductor package according to claim 8, wherein the first semiconductor chip comprises a logic device, and the second semiconductor chip comprises a memory device.

10. The semiconductor package according to claim 1, wherein each of the at least one first insulating interlayer comprises an inorganic insulating material.

11. A semiconductor package comprising:
a redistribution layer (RDL) comprising:
an insulating interlayer comprising an inorganic insulating material;
a redistribution wiring in the insulating interlayer;
a first conductive pad on the insulating interlayer, a sidewall of the first conductive pad having an inclination with respect to an upper surface of the insulating interlayer;
a second conductive pad spaced apart from the first conductive pad in a horizontal direction on the insulating interlayer, a sidewall of the second conductive pad being perpendicular with respect to the upper surface of the insulating interlayer; and
a protective layer on the insulating interlayer, and on a sidewall of each of the first conductive pad and the second conductive pad and an edge of an upper surface of each of the first conductive pad and the second conductive pad, the protective layer comprising a photo imageable dielectric (PID);
a semiconductor chip on the RDL, the semiconductor chip electrically connected to the first conductive pad and the second conductive pad; and
a molding layer on the RDL and the semiconductor chip.

12. The semiconductor package according to claim 11, wherein the inclination of the sidewall of the first conductive pad is 70° to 80° with respect to the upper surface of the insulating interlayer.

13. The semiconductor package according to claim 11, wherein the RDL further comprises:
a third conductive pad spaced apart from the first conductive pad and the second conductive pad in the horizontal direction, the third conductive pad comprising:
a lower portion extending through the insulating interlayer and contacting the redistribution wiring; and
an upper portion on the lower portion, the upper portion having a sidewall slanted with respect to the upper surface of the insulating interlayer, and
wherein the protective layer is on the sidewall of the upper portion of the third conductive pad and an edge of an upper surface of the third conductive pad.

14. The semiconductor package according to claim 13, further comprising a conductive post contacting an upper surface of the third conductive pad and extending in a vertical direction,
wherein the molding layer is on a sidewall of the conductive post.

15. A semiconductor package comprising:
a first redistribution layer (RDL) comprising:
at least one first insulating interlayer;
at least one first redistribution wiring in the at least one first insulating interlayer;
a first conductive pad on an uppermost one of the at least one first insulating interlayer, a sidewall of the first conductive pad having an inclination with respect to an upper surface of the uppermost one of the at least one first insulating interlayer; and
a first protective layer on the uppermost one of the at least one first insulating interlayer, and on the sidewall of the first conductive pad and an edge of an upper surface of the first conductive pad;
a first conductive connection member on a lower surface of the first RDL and contacting a portion of the at least one first redistribution wiring;
a second conductive connection member on the first RDL and contacting the first conductive pad;
a first semiconductor chip on an upper surface of the second conductive connection member;
a first molding layer on the first RDL, the first semiconductor chip, and the second conductive connection member;
a second RDL on the first molding layer, the second RDL comprising at least one second redistribution wiring and a second conductive pad;
a third conductive connection member on the second RDL and contacting the second conductive pad; and
a second semiconductor chip contacting an upper surface of the third conductive connection member.

16. The semiconductor package according to claim 15, wherein the inclination of the sidewall of the first conductive pad is 70° to 80° with respect to the upper surface of the uppermost one of the at least one first insulating interlayer.

17. The semiconductor package according to claim 15, wherein the second conductive pad is spaced apart from the first conductive pad in a horizontal direction, and the second conductive pad comprises:
a lower portion extending through the uppermost one of the at least one first insulating interlayer and contacting a portion of the at least one first redistribution wiring; and
an upper portion on the lower portion, the upper portion having a sidewall slanted with respect to the upper surface of the uppermost one of the at least one first insulating interlayer, and
wherein the first protective layer is on the sidewall of the upper portion of the second conductive pad and an edge of an upper surface of the second conductive pad.

18. The semiconductor package according to claim 17, further comprising a conductive post contacting an upper surface of the second conductive pad, and extending in a vertical direction,
wherein the first molding layer is on a sidewall of the conductive post.

19. The semiconductor package according to claim 18, wherein the second RDL is on the first molding layer and the conductive post,
the second RDL further comprises:
at least one second insulating interlayer;
a third conductive pad on an uppermost one of the at least one second insulating interlayer, a sidewall of the third conductive pad having an inclination with respect to an upper surface of the uppermost one of the at least one second insulating interlayer; and
a second protective layer on the uppermost one of the at least one second insulating interlayer, and on the sidewall of the third conductive pad and an edge of an upper surface of the third conductive pad, and
wherein the at least one second redistribution wiring is in the at least one second insulating interlayer, and is electrically connected to the conductive post.

20. The semiconductor package according to claim 15, wherein each of the at least one first insulating interlayer comprises an inorganic insulating material, and the first protective layer comprises an organic insulating material.
